(19) United States
(12) Patent Application Publication
(10) Pub. No.: US 2025/0356884 A1
(43) Pub. Date: Nov. 20, 2025

(54) MEMORY LAYOUT

(71) Applicant: CXMT Corporation, Hefei (CN)

(72) Inventors: Yicheng Gao, Hefei, Anhui (CN); Jaeyong Cha, Hefei, Anhui (CN)

(73) Assignee: CXMT Corporation, Hefei (CN)

(21) Appl. No.: 19/286,463

(22) Filed: Jul. 31, 2025

Related U.S. Application Data
(63) Continuation of application No. PCT/CN2023/095115, filed on May 18, 2023.

(30) Foreign Application Priority Data
Feb. 2, 2023 (CN) 202310115161.4

(51) Int. Cl. G11C 5/02; G11C 5/06; G11C 11/4091; H10D 89/10

(52) U.S. Cl. CPC G11C 5/025; G11C 5/063; G11C 11/4091; H10D 89/10

(57) ABSTRACT

A memory layout is disclosed. The memory layout includes multiple memory arrays arranged in a preset direction and a local amplifier located between adjacent memory arrays. The local amplifier is configured to implement data transmission between a local data line and a global data line. The local amplifier includes multiple transistors arranged perpendicular to the preset direction, where the multiple transistors have a common active region, each of the multiple transistors has a corresponding gate structure, the multiple gate structures are located in the active region and arranged at intervals perpendicular to the preset direction, and the gate structures extend in the preset direction. The local amplifier further includes multiple conductive plugs located in the active region and disposed at intervals from the gate structures, where the conductive plugs extend in the preset direction.

### CROSS-REFERENCE TO RELATED APPLICATIONS

This application is a continuation of International Patent Application No. PCT/CN2023/095115, filed on May 18, 2023, which claims priority to Chinese Patent Application No. 202310115161.4, filed on Feb. 2, 2023 and entitled “MEMORY LAYOUT”. The above-referenced applications are incorporated herein by reference in its entirety.

### TECHNICAL FIELD

Embodiments of the present disclosure relate to the field of semiconductor technologies, and in particular, to a memory layout.

### BACKGROUND

A dynamic random access memory (Dynamic Random Access Memory, DRAM) completes data write operations to the memory by storing charge in capacitors of memory cells, and completes data read operations from the memory by reading charge in capacitors of memory cells.

A layout design of the memory is an indispensable design phase for manufacturing an integrated circuit. The layout design not only relates to whether a function of the integrated circuit is correct, but also greatly affects the performance, costs, and power consumption of the integrated circuit. However, a current layout floorplan of the memory still has problems such as insufficient utilization of a layout area and unreasonable arrangement of devices. These problems about the layout floorplan affect a size of a device forming the memory, and further affect the performance of the memory.

### SUMMARY

An embodiment of the present disclosure provides a memory layout, including: multiple memory arrays arranged in a preset direction; and a local amplifier located between adjacent memory arrays. The local amplifier is configured to implement data transmission between a local data line and a global data line. The local amplifier includes multiple transistors arranged perpendicular to the preset direction, where the multiple transistors have a common active region, each of the multiple transistors has a corresponding gate structure, the multiple gate structures are located in the active region and arranged at intervals perpendicular to the preset direction, and the gate structures extend in the preset direction. The local amplifier includes multiple conductive plugs located in the active region and disposed at intervals from the gate structures, where the conductive plugs extend in the preset direction.

In some embodiments, the active region includes multiple source/drain regions arranged at intervals perpendicular to the preset direction and a channel region located between adjacent source/drain regions. The gate structures are located in the channel region, the conductive plugs are located in the source/drain regions, and the conductive plugs in the adjacent source/drain regions are aligned with each other in a direction perpendicular to the preset direction.

In some embodiments, the active region includes multiple source/drain regions arranged at intervals perpendicular to the preset direction and a channel region located between adjacent source/drain regions. The gate structures are located in the channel region, the conductive plugs are located in the source/drain regions, and the conductive plugs in the adjacent source/drain regions are staggered with each other in a direction perpendicular to the preset direction.

In some embodiments, each of the source/drain regions has only one conductive plug.

In some embodiments, each of the source/drain regions has multiple the conductive plugs arranged at intervals in the preset direction.

In some embodiments, the memory layout further includes a first conductive layer, where the first conductive layer is formed by multiple mutually independent first traces extending in the preset direction, the first traces are connected to the source/drain regions through the conductive plugs or the first traces are connected to the gate structures, and each of the first traces connected to each of the source/drain regions transmits an electrical signal in the preset direction.

In some embodiments, the memory layout further includes a first conductive layer, where the first conductive layer is formed by multiple mutually independent first traces extending in the preset direction, the first traces are connected to the source/drain regions through the conductive plugs or the first traces are connected to the gate structures, each of the first traces connected to each of the source/drain regions includes a first conductive portion and a second conductive portion that are isolated from each other, the first conductive portion is configured to extend in the preset direction and transmit an electrical signal, the second conductive portion is configured to serve as an intermediate transmission structure between a second conductive layer and the source/drain region, and the second conductive layer is located above the first conductive layer.

In some embodiments, in the preset direction, the length of the second conductive portion is less than the length of the source/drain region, and the length of the first conductive portion is greater than the length of the source/drain region.

In some embodiments, some of the first traces include the first conductive portion and two second conductive portions, and the two second conductive portions are located on two opposite sides of the first conductive portion.

In some embodiments, the memory layout further includes a sense amplifier located between the adjacent memory arrays. The sense amplifier is configured to sense and amplify data of a bit line. The sense amplifier includes an amplification transistor for performing sensing and amplification and a transmission transistor for transmitting a power signal, a direction of the transmission transistor toward the local amplifier is perpendicular to the preset direction, and a gate structure of the transmission transistor extends in the preset direction.

In some embodiments, the amplification transistor and the transmission transistor are arranged in the preset direction, and a gate structure of the amplification transistor extends in the preset direction.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1 is a schematic diagram of a circuit structure of a memory;

FIG. 2 is a schematic diagram of a circuit structure of a local amplifier;

FIG. 3 is a schematic diagram of a memory layout in a related technology;

FIG. 4 is a schematic diagram of a memory layout according to an embodiment of the present disclosure;

FIG. 5 is a partial schematic diagram of a memory layout according to an embodiment of the present disclosure;

FIG. 6 is a partial schematic diagram of another memory layout according to an embodiment of the present disclosure;

FIG. 7 is a partial schematic diagram of another memory layout according to an embodiment of the present disclosure;

FIG. 8 is a partial schematic diagram of another memory layout according to an embodiment of the present disclosure;

FIG. 9 is a partial schematic diagram of another memory layout according to an embodiment of the present disclosure;

FIG. 10 is a schematic structural diagram of a first trace that does not form an isolation structure according to an embodiment of the present disclosure;

FIG. 11 is a schematic structural diagram of a first trace that forms an isolation structure according to an embodiment of the present disclosure; and

FIG. 12 is a schematic diagram of another memory layout according to an embodiment of the present disclosure.

### DESCRIPTION OF EMBODIMENTS

It can be learned from the BACKGROUND section that problems such as insufficient utilization of a layout area and unreasonable arrangement of devices affect the performance of the memory.

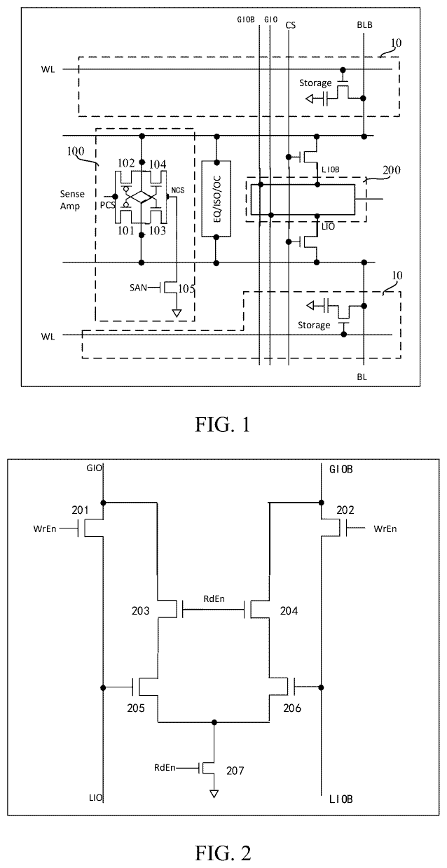

FIG. 1 is a schematic diagram of a circuit structure of a memory. Referring to FIG. 1, a memory structure includes multiple memory arrays 10, and each memory array 10 includes multiple memory cells. Each of the memory cells may be of a 1T1C (1 transistor 1 capacitance) structure formed by one cell transistor and one cell capacitor. In addition, the memory structure may further include a sense amplifier 100, a local amplifier 200, an equalization circuit, and an input/output circuit that are disposed between adjacent memory arrays.

One of a source or a drain of the cell transistor is connected to the cell capacitor, and the other is connected to a bit line BL/complementary bit line BLB. A word line WL is connected to a gate of the cell transistor, and is configured to choose to turn on the gate of the corresponding cell transistor, so that the cell capacitor is connected to the bit line BL/complementary bit line BLB, thereby writing an electrical signal in the bit line BL/complementary bit line BLB into the cell capacitor, or reading an electrical signal from the cell capacitor to the bit line BL/complementary bit line BLB.

The equalization circuit is connected to the bit line BL and the complementary bit line BLB, and is configured to equalize a voltage between the bit line BL and the complementary bit line BLB in a precharge phase. The input/output circuit includes an input/output transistor. One of a source or a drain of the input/output transistor is connected to the bit line BL/complementary bit line BLB, and the other is connected to a local data line LIO/complementary local data line LIOB. A gate of the input/output transistor is configured to receive a select signal CS, and choose to turn on an input/output transistor corresponding to the select signal based on the select signal CS, so that the bit line BL/complementary bit line BLB is connected to the local data line LIO/complementary local data line LIOB, thereby implementing data transfer between the bit line BL/complementary bit line BLB and the local data line LIO/complementary local data line LIOB.

The sense amplifier 100 is connected between the bit line BL and the complementary bit line BLB, and the sense amplifier 100 is configured to receive and amplify a voltage difference between the bit line BL and the complementary bit line BLB based on a first power signal PCS and a second power signal NCS. Specifically, the sense amplifier 100 includes an amplification transistor (a first amplification PMOS transistor 101, a second amplification PMOS transistor 102, a first amplification NMOS transistor 103, and a second amplification NMOS transistor 104 shown in FIG. 1) for performing sensing and amplification and a transmission transistor for transmitting a power signal. The transmission transistor is an NMOS transistor 105 configured to transmit a low level signal and a PMOS transistor (not shown) configured to transmit a high level signal.

The local data line LIO is connected to the global data line GIO through the local amplifier 200, thereby implementing data transmission between the local data line LIO and the global data line GIO. The complementary local data line LIOB is connected to the complementary global data line GIOB through the local amplifier 200, so as to implement data transmission between the complementary local data line LIOB and the complementary global data line GIOB.

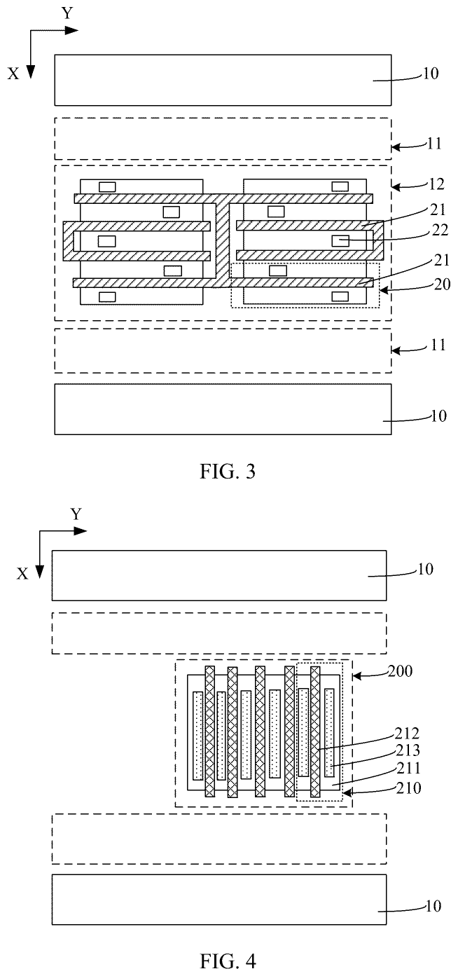

FIG. 2 is a schematic diagram of a circuit structure of a local amplifier. FIG. 3 is a schematic diagram of a memory layout in a related technology. Referring to FIG. 2, the local amplifier 200 includes multiple transistors, which may be classified into a first transistor 201, a second transistor 202, a third transistor 203, a fourth transistor 204, a fifth transistor 205, a sixth transistor 206, and a seventh transistor 207. A gate of the first transistor 201 and a gate of the second transistor 202 are configured to receive a write enable signal. One of a source or a drain of the first transistor 201 is connected to the global data line GIO, and the other is connected to the local data line LIO. One of a source or a drain of the second transistor 202 is connected to the complementary global data line GIOB, and the other is connected to the complementary local data line LIOB. A gate of the third transistor 203, a gate of the fourth transistor 204, and a gate of the seventh transistor 207 are configured to receive a read enable signal. One of a source or a drain of the third transistor 203 is connected to the global data line GIO, and the other is connected to a source or a drain of the fifth transistor 205. One of a source or a drain of the fourth transistor 204 is connected to the complementary global data line GIOB, and the other is connected to a source or a drain of the sixth transistor 206. A gate of the fifth transistor 205 is connected to the local data line LIO. A gate of the sixth transistor 206 is connected to the complementary local data line LIOB. The other of the source or the drain of the fifth transistor 205 is connected to a drain of the seventh transistor 207. The other of the source or the drain of the sixth transistor 206 is connected to the drain of the seventh transistor 207. A source of the seventh transistor 207 is grounded.

Referring to FIG. 2 and FIG. 3, the first transistor 201, the second transistor 202, the third transistor 203, the fourth transistor 204, the fifth transistor 205, the sixth transistor 206, and the seventh transistor 207 are referred to as a transistor group. The transistor group includes multiple transistors 20 of the local amplifier 200. In a related technology, a layout floorplan of the multiple transistors 20 in the local amplifier is shown in FIG. 3. Memory arrays 10 are arranged in a first direction X. A first region 11 in which a sense amplifier is disposed and a second region 12 in which a local amplifier is disposed are included between adjacent memory arrays 10 that are arranged in the first direction X. It can be seen that gates 21 of transistors 20 of the local amplifier located in the second region 12 each extend in a second direction Y. The second direction Y is perpendicular to the first direction X, and the transistors 20 are arranged in the first direction X. Because the memory arrays 10 are arranged in the first direction X, the length of the second region 12 reserved for the transistors 20 of the local amplifier is limited. Therefore, a quantity of the transistors 20 of the local amplifier arranged in the first direction X is limited. In addition, a size of a conductive plug 22 configured to lead out a source and a drain of a transistor 20 in the second direction Y is limited by the width of a corresponding bonding wire, there is a limitation on a minimum spacing between adjacent conductive plugs 22 in the second direction Y, and a size of each of the conductive plugs 22 in the first direction X is limited by an adjacent gate 21. Therefore, conductive plugs 22 in a source region and a drain region can only be set to a state in which a total area is relatively small, and the conductive performance of the conductive plugs 22 is poor.

To resolve the foregoing problems, an embodiment of the present disclosure provides a memory layout in which multiple transistors of a local amplifier are disposed to be arranged perpendicular to a preset direction, thereby avoiding a limitation imposed by a limited spacing between memory arrays on a quantity of transistors, and further implementing relatively dense arrangement of transistors and helping ensure full utilization of a layout area. In addition, gate structures of multiple transistors of the local amplifier are disposed to extend in a preset direction. This helps alleviate a limitation imposed by an adjacent gate structure on the size of the conductive plug in the preset direction, and enables the conductive plug to extend in the preset direction, and further ensures that the conductive plug has a relatively large size in the preset direction. Employing the conductive plug with a relatively large size as a lead-out wire in an active region of the transistor helps reduce on-resistance of the lead-out wire, and further helps improve the electrical performance of the memory.

The embodiments of the present disclosure are described in detail below with reference to the accompanying drawings. However, it may be understood by a person of ordinary skill in the art that in the embodiments of the present disclosure, many technical details are provided to enable readers to better understand the embodiments of the present disclosure. However, the technical solutions claimed in the embodiments of the present disclosure may be implemented even without these technical details and various changes and modifications made based on the following embodiments.

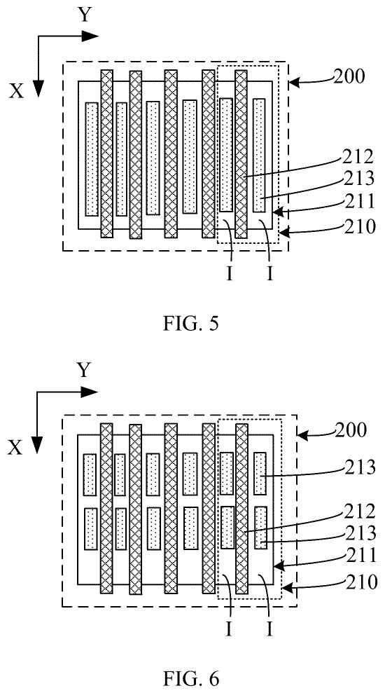

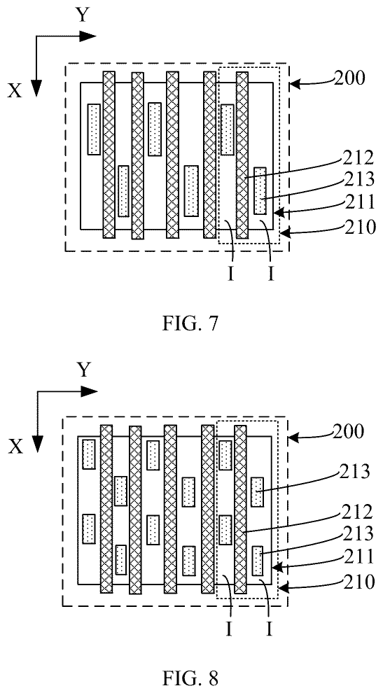

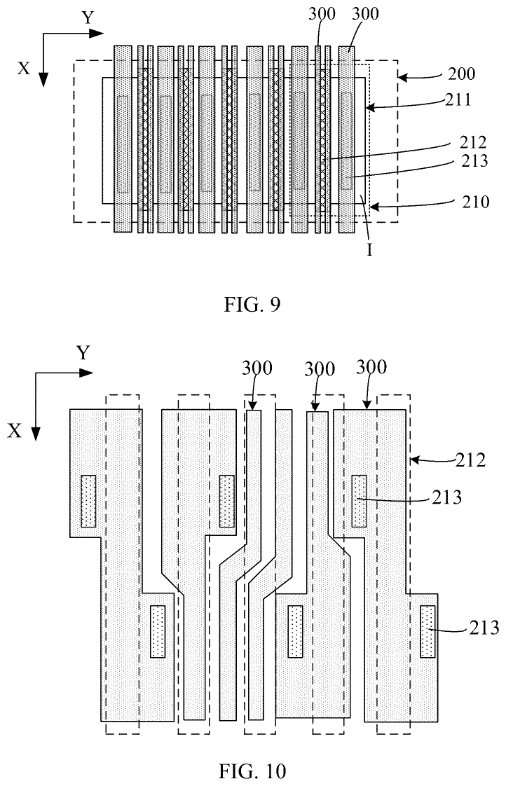

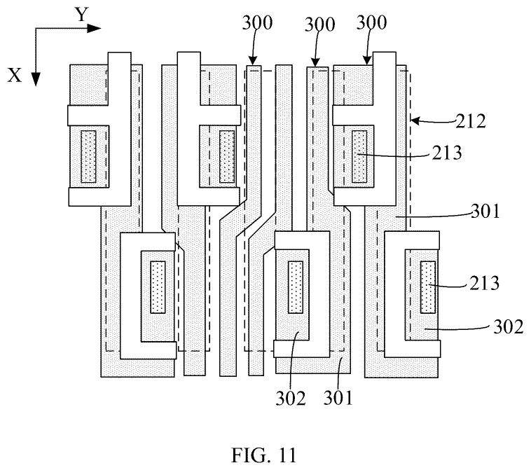

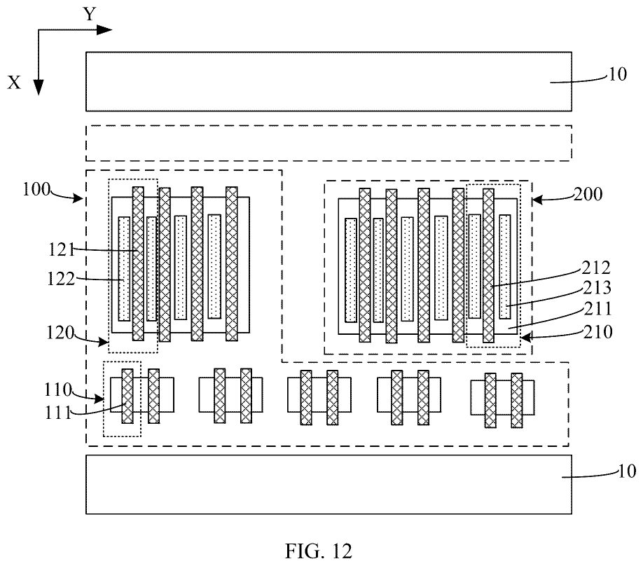

FIG. 4 is a schematic diagram of a memory layout according to an embodiment of the present disclosure. FIG. 5 is a partial schematic diagram of a memory layout according to an embodiment of the present disclosure. FIG. 6 is a partial schematic diagram of another memory layout according to an embodiment of the present disclosure. FIG. 7 is a partial schematic diagram of another memory layout according to an embodiment of the present disclosure. FIG. 8 is a partial schematic diagram of another memory layout according to an embodiment of the present disclosure. FIG. 9 is a partial schematic diagram of another memory layout according to an embodiment of the present disclosure. FIG. 10 is a schematic structural diagram of a first trace that does not form an isolation structure according to an embodiment of the present disclosure. FIG. 11 is a schematic structural diagram of a first trace that forms an isolation structure according to an embodiment of the present disclosure. FIG. 12 is a schematic diagram of another memory layout according to an embodiment of the present disclosure.

Referring to FIG. 4, the memory layout includes: multiple memory arrays 10 arranged in a preset direction; and a local amplifier 200 located between adjacent memory arrays 10. The local amplifier 200 is configured to implement data transmission between a local data line and a global data line. The preset direction is an arrangement direction of the multiple memory arrays 10, namely, a first direction X shown in FIG. 4 to FIG. 12. It should be noted that the preset direction is also an extension direction of a bit line.

The local amplifier 200 includes transistor groups arranged in a second direction Y. Each transistor group includes multiple transistors 210 arranged in the second direction Y. The multiple transistors 210 may correspond to the first transistor 201, the second transistor 202, the third transistor 203, the fourth transistor 204, the fifth transistor 205, the sixth transistor 206, and the seventh transistor 207 in FIG. 2. The second direction Y is perpendicular to the first direction X.

The multiple transistors 210 of the local amplifier 200 may have a common active region 211, the active region 211 may be a semiconductor layer with doping elements, and the active region 211 is configured to serve as a source region, a drain region, and a channel region of a transistor 210. The multiple transistors 210 each have a corresponding gate structure 212, the multiple gate structures 212 are located in the active region 211 and arranged at intervals in the second direction Y, and the gate structures 212 extend in the first direction X. It should be noted that a quantity of transistors 210 arranged in the second direction Y is not limited in this embodiment of the present disclosure, and may be adjusted based on an actual circuit structure of the local amplifier and a size of the transistor.

The gate structure 212 serves as a gate of the transistor 210, and is configured to implement conduction of the source and drain of the transistor 210 based on a control signal. Arranging the multiple transistors 210 of the local amplifier 200 in the second direction Y helps alleviate a limitation imposed by a limited spacing between memory arrays 10 on a quantity of transistors 210 of the local amplifier 200, and further implements relatively dense arrangement of transistors 210 and helps ensure full utilization of a layout area. In addition, if the multiple transistors 210 are all arranged in the first direction X, adjusting the width of a region in which the local amplifier 200 is disposed in the first direction X affects a quantity of transistors 210 arranged in the first direction X. When a layout floorplan in which the multiple transistors 210 are arranged in the second direction Y is employed, the width of the region in which the local amplifier 200 is disposed in the first direction X may be adjusted by adjusting a size of the transistor 210 in the first direction X, thereby avoiding a limitation imposed by the quantity of transistors of the local amplifier 200 on a layout floorplan between adjacent memory arrays 10, and helping improve the flexibility of the layout floorplan between adjacent memory arrays 10 and the convenience of adjusting the size of the transistor.

Still referring to FIG. 4, the local amplifier 200 further includes multiple conductive plugs 213 located in the active region 211 and disposed at intervals from the gate structures 212, and the conductive plugs 213 extend in the first direction X. The conductive plugs 213 are configured to lead out sources or drains of the transistors 210, so that the sources or drains of the transistors 210 are connected to a bonding wire in a wiring layer located above the active region 211.

It should be noted that a size of a conductive plug in the second direction Y is limited by the width of a corresponding bonding wire, and there is a limitation on a minimum spacing between adjacent conductive plugs in the second direction Y. Therefore, if the gate structure of the transistor extends in the second direction Y, even if the source region and the drain region of the transistor have a relatively long size in the second direction Y, the conductive plug located in the source region or the drain region cannot be designed to a state in which extension in the second direction Y is relatively long. Therefore, to maximize the size of the conductive plug in the source region or the drain region, only multiple conductive plugs arranged in the second direction Y can be disposed, as shown in FIG. 3, and there is a relatively large spacing between adjacent conductive plugs arranged in the second direction Y. However, the size of the conductive plug in the first direction X is limited by an adjacent gate structure. Therefore, the conductive plugs in the source region and the drain region can only be set to a state in which a total area is relatively small, and the conductive performance is poor.

Referring to FIG. 4, the gate structure 212 of the transistor 210 extends in the first direction X, and in this case the source region and the drain region of the transistor 210 have a relatively long size in the first direction X, so that the conductive plug 213 has a relatively large size in the first direction X. This avoids a limitation imposed by an adjacent gate structure 212 on the size of the conductive plug 213 in the first direction X, and ensures that the conductive plug 213 has a relatively large size. Employing the conductive plug 213 with a relatively large size as a lead-out wire of the source region or the drain region of the transistor 210 helps reduce on-resistance of the lead-out wire, and further helps improve the electrical performance of the memory. In addition, in the second direction Y, a spacing between adjacent conductive plugs 213 is partially occupied by the gate structure 212, thereby helping improve the utilization efficiency of the layout.

In some embodiments, referring to FIG. 5, an active region 211 includes multiple source/drain regions I arranged at intervals in the second direction Y and a channel region located between adjacent source/drain regions I. The source/drain regions I are the source regions or the drain regions of the transistors 210. The gate structures 212 are located in the channel region, the conductive plugs 213 are located in the source/drain regions I, and the conductive plugs 213 in the adjacent source/drain regions I are aligned with each other in the second direction Y. There is a gate structure 212 between the conductive plugs 213 in the adjacent source/drain regions I, and a spacing between adjacent conductive plugs 213 in the second direction Y has to meet a requirement. Therefore, if a size of the gate structure 212 is relatively large in the second direction Y, so that a distance between the conductive plugs 213 on two sides of the gate structure 212 meets a spacing requirement, the conductive plugs 213 in the adjacent source/drain regions I may be aligned with each other in the second direction Y. This helps prevent the two adjacent conductive plugs 213 from being limited by each other, so that the conductive plugs 213 have a relatively long size in the first direction X, thereby helping improve the electrical performance of the memory.

In some embodiments, referring to FIG. 5, the conductive plugs 213 in the adjacent source/drain regions I are aligned with each other in the second direction Y, and each of the source/drain regions I has only one conductive plug 213. In this way, the length of the conductive plug 213 in each of the source/drain regions I can be maximized in the first direction X, thereby helping ensure a maximum overall size of the conductive plug 213, and further helping improve the electrical performance of the memory.

In some embodiments, each of the source/drain regions I has only one conductive plug 213, and the conductive plug 213 is located in a middle position of the corresponding source/drain region I.

In some embodiments, referring to FIG. 6, the conductive plugs 213 in the adjacent source/drain regions I are aligned with each other in the second direction Y, and each of the source/drain regions I has multiple conductive plugs 213 arranged at intervals in the first direction X. In the first direction X, there is no spacing requirement between adjacent conductive plugs 213. However, if a size of a conductive plug 213 in the first direction X is excessively long, there may be a problem that collapse occurs easily. Therefore, multiple conductive plugs 213 arranged at intervals in the first direction X may alternatively be disposed in one source/drain region I.

In some embodiments, a quantity of the conductive plugs 213 in one source/drain region I may be 2, 3, or 4. The lengths of different conductive plugs 213 in the same source/drain region I in a preset direction may be the same or different, and may be adjusted based on a size of the source/drain region I and the conductive plugs.

In some embodiments, referring to FIG. 7, the active region 211 includes multiple source/drain regions I arranged at intervals in a second direction Y and a channel region located between adjacent source/drain regions I. The gate structures 212 are located in the channel region, the conductive plugs 213 are located in the source/drain regions I, and the conductive plugs 213 in the adjacent source/drain regions I are staggered with each other in the second direction Y. There is a gate structure 212 between the conductive plugs 213 in the adjacent source/drain regions I, and a spacing between adjacent conductive plugs 213 in the second direction Y has to meet a requirement. Therefore, when a size of the gate structure 212 is relatively small in the second direction Y, if the conductive plugs 213 in the adjacent source/drain regions I are aligned with each other in the second direction Y, a distance between the conductive plugs 213 on two sides of the gate structure 212 may be unable to meet a spacing requirement. Therefore, the conductive plugs 213 in the adjacent source/drain regions I are staggered with each other in the second direction Y, thereby helping ensure that the conductive plugs 213 have a relatively long size in the first direction X when the spacing requirement is met, and further helping improve the electrical performance of the memory.

In some embodiments, referring to FIG. 7, the conductive plugs 213 in the adjacent source/drain regions I are staggered with each other in the second direction Y, and each of the source/drain regions I has only one conductive plug 213. To be specific, when the size of the gate structure 212 in the second direction Y is relatively small, if the conductive plugs 213 in the adjacent source/drain regions I are aligned with each other, a distance between the conductive plugs 213 on two sides of the gate structure 212 may be unable to meet a spacing requirement. Therefore, the conductive plugs 213 in the adjacent source/drain regions I are staggered with each other in the second direction Y. When the conductive plugs 213 in the adjacent source/drain regions I are staggered with each other, only one conductive plug 213 is disposed in each of the source/drain regions I, so that the length of the conductive plug 213 in each of the source/drain regions I can be maximized when the spacing requirement is met, thereby helping ensure a maximum overall size of the conductive plug 213, and further helping improve the electrical performance of the memory.

In some embodiments, referring to FIG. 8, the conductive plugs 213 in the adjacent source/drain regions I are staggered with each other in the second direction Y, and each of the source/drain regions I has multiple conductive plugs 213 arranged at intervals in the first direction X. To be specific, when the size of the gate structure 212 in the second direction Y is relatively small, to meet the spacing requirement, the conductive plugs 213 on the adjacent source/drain regions I are staggered with each other. When the conductive plugs 213 on the adjacent source/drain regions I are staggered with each other, multiple conductive plugs 213 arranged at intervals in the first direction X may alternatively be disposed in each of the source/drain regions I.

In some embodiments, a quantity of the conductive plugs 213 in one source/drain region I may be 2, 3, or 4. The lengths of different conductive plugs 213 in the same source/drain region I in a preset direction may be the same or different, and may be adjusted based on a size of the source/drain region I and the conductive plugs.

In some embodiments, referring to FIG. 9, the memory layout further includes a first conductive layer. The first conductive layer is formed by multiple mutually independent first traces 300 extending in the first direction X, the first traces 300 are connected to the source/drain regions I through the conductive plugs 213 or the first traces 300 are connected to the gate structures 212, and each of the first traces 300 connected to each of the source/drain regions I transmits an electrical signal in the first direction X. The first conductive layer is a wiring layer, and the first conductive layer is located on a side, away from the active region 211, of the conductive plug 213 and on a side, away from the active region 211, of the gate structure 212.

Referring to FIG. 10 and FIG. 11, in some embodiments, the first conductive layer is formed by multiple mutually independent first traces 300 extending in the first direction X, the first traces 300 are connected to the source/drain regions through the conductive plugs 213 or the first traces 300 are connected to the gate structures 212, each of the first traces 300 connected to each of the source/drain regions includes a first conductive portion 301 and a second conductive portion 302 that are isolated from each other, the first conductive portion 301 is configured to extend in the first direction X and transmit an electrical signal, the second conductive portion 302 is configured to serve as an intermediate transmission structure between a second conductive layer and the source/drain region, and the second conductive layer is located above the first conductive layer. Some of the first traces 300 are not connected to the source/drain region, and do not need to be cropped. Others of the first traces 300 are connected to the source/drain region, and are cropped into a first conductive portion 301 and a second conductive portion 302 that are isolated from each other. To be specific, steps of forming the first conductive portion 301 and the second conductive portion 302 are as follows: Referring to FIG. 10, complete first traces 300 extending in the first direction X are first formed. Referring to FIG. 11, a first trace 300 connected to the source/drain region is cropped, so that some of the first traces 300 located above the conductive plug 213 form an independent structure, which serves as the second conductive portion 302, and the remaining first traces 300 extend in the first direction X and serve as the first conductive portion 301. This helps make the first traces 300 of the first conductive layer more dense, increase a quantity of available traces and a quantity of signals that can be transmitted, and implement reasonable utilization of layout space.

It should be noted that the second conductive portion 302 connected to the conductive plug 213 is configured to serve as an intermediate transmission structure between the second conductive layer and the source/drain region. In other words, instead of directly employing the first traces 300 in the first conductive layer to lead out the signal transmitted by the conductive plug 213 connected to the source/drain region, the second conductive portion 302 is employed to lead out the source/drain region to the second conductive layer above the first conductive layer, and the traces in the second conductive layer are employed to lead out corresponding signals. In FIG. 10, a projection position of the gate structure is identified by a dashed-line block.

In some embodiments, referring to FIG. 7 and FIG. 11, in the first direction X, the length of the second conductive portion 302 is less than the length of the source/drain region I, and the length of the first conductive portion 301 is greater than the length of the source/drain region I. This helps prevent the second conductive portion 302 leading out the conductive plug 213 from occupying excessive space of the first conductive layer.

In some embodiments, referring to FIG. 11, some of the first traces 300 include the first conductive portion 301 and two second conductive portions 302, and the two second conductive portions 302 are located on two opposite sides of the first conductive portion 301. In other words, each of the second conductive portions 302 on two sides of the first conductive portion 301 extending in the first direction X may be formed by cropping the same first trace 300. In other embodiments, some of the first traces include the first conductive portion and at least three second conductive portions. In the first direction X, different second conductive portions appear alternately on left and right sides. In other words, in the first direction X, adjacent second conductive portions are located on two opposite sides of the first conductive portion.

In some embodiments, referring to FIG. 12, the memory layout further includes a sense amplifier 100 located between adjacent memory arrays 10. The sense amplifier 100 is configured to sense and amplify data of a bit line. The sense amplifier 100 includes an amplification transistor 110 for performing sensing and amplification and a transmission transistor 120 for transmitting a power signal, a direction of the transmission transistor 120 toward the local amplifier 200 is a second direction Y, and a gate structure 121 of the transmission transistor 120 extends in the first direction X. The amplification transistor 110 corresponds to a first amplification PMOS transistor 101, a second amplification PMOS transistor 102, a first amplification NMOS transistor 103, and a second amplification NMOS transistor 104 in FIG. 1. The transmission transistor 120 corresponds to an NMOS transistor 105 configured to transmit a low level signal and a PMOS transistor (not shown in the figure) configured to transmit a high level signal in FIG. 1.

Similar to the transistor 210 of the local amplifier 200, the transmission transistor 120 includes a channel region at the bottom of the gate structure 121 and a source/drain region on two sides of the channel region. The source/drain region of the transmission transistor 120 has a conductive plug 122 configured to lead out the source/drain region, the transmission transistor 120 and the local amplifier 200 are arranged in the second direction Y, and the gate structure 121 of the transmission transistor 120 extends in the first direction X. In this way, the conductive plug 122 of the transmission transistor 120 extends in the first direction X, thereby helping ensure that the conductive plug 122 of the transmission transistor 120 has a relatively large size, and further helping improve the electrical performance of the memory.

In some embodiments, the first conductive layer is also located above the transmission transistor, and the first trace extending in the first direction X is connected to the gate structure of the transmission transistor, or is connected to the source/drain region of the transmission transistor through the conductive plug.

In some embodiments, referring to FIG. 12, the amplification transistor 110 and the transmission transistor 120 are arranged in the first direction X, and the gate structure 111 of the amplification transistor 110 extends in the first direction X. An extension direction of the gate structure 111 of the amplification transistor 110 is set to be the first direction X, thereby helping adjust a spacing between adjacent memory arrays 10 by adjusting a size of the amplification transistor 110 in the first direction X, and helping improve the flexibility of a layout floorplan of the memory.

In the memory layout provided in the foregoing embodiments, transistors of a local amplifier are disposed to be arranged perpendicular to a preset direction, thereby avoiding a limitation imposed by a limited spacing between memory arrays on a quantity of transistors of the local amplifier, and further implementing relatively dense arrangement of transistors and helping ensure full utilization of a layout area. In addition, gate structures of the transistors are disposed to extend in a preset direction. This helps alleviate a limitation imposed by an adjacent gate structure on the size of the conductive plug in the preset direction, and enables the conductive plug to extend in the preset direction, and ensures that the conductive plug has a relatively large size in the preset direction. Employing the conductive plug with a relatively large size as a lead-out wire in an active region of the transistor helps reduce on-resistance of the lead-out wire, and further helps improve the electrical performance of the memory.

A person of ordinary skill in the art may understand that the foregoing implementations are specific embodiments for implementing the present disclosure. In actual application, various changes may be made to the forms and details of the implementations without departing from the spirit and scope of the present disclosure. Any person skilled in the art may make variations and modifications without departing from the spirit and scope of the present disclosure. Therefore, the protection scope of the present disclosure shall be subject to the scope defined by the claims.

1. A memory layout, comprising:
a plurality of memory arrays arranged in a preset direction; and
a local amplifier located between adjacent memory arrays, the local amplifier being configured to implement data transmission between a local data line and a global data line;
the local amplifier comprising a plurality of transistors arranged perpendicular to the preset direction, the plurality of transistors having a common active region, each of the plurality of transistors having a corresponding gate structure, the plurality of gate structures being located in the active region and arranged at intervals perpendicular to the preset direction, and the gate structures extending in the preset direction; and
the local amplifier comprising:
a plurality of conductive plugs located in the active region and disposed at intervals from the gate structures, the conductive plugs extending in the preset direction.

2. The memory layout according to claim 1, wherein the active region comprises a plurality of source/drain regions arranged at intervals perpendicular to the preset direction and a channel region located between adjacent source/drain regions;
the gate structures are located in the channel region, the conductive plugs are located in the source/drain regions, and the conductive plugs in the adjacent source/drain regions are aligned with each other in a direction perpendicular to the preset direction.

3. The memory layout according to claim 1, wherein the active region comprises a plurality of source/drain regions arranged at intervals perpendicular to the preset direction and a channel region located between adjacent source/drain regions;
the gate structures are located in the channel region, the conductive plugs are located in the source/drain regions, and the conductive plugs in the adjacent source/drain regions are staggered with each other in a direction perpendicular to the preset direction.

4. The memory layout according to claim 2, wherein each of the source/drain regions has only one conductive plug.

5. The memory layout according to claim 2, wherein each of the source/drain regions has a plurality of the conductive plugs arranged at intervals in the preset direction.

6. The memory layout according to claim 2, further comprising a first conductive layer, wherein the first conductive layer is formed by a plurality of mutually independent first traces (300) extending in the preset direction, the first traces are connected to the source/drain regions through the conductive plugs or the first traces are connected to the gate structures, and each of the first traces connected to each of the source/drain regions transmits an electrical signal in the preset direction.

7. The memory layout according to claim 2, further comprising a first conductive layer, wherein the first conductive layer is formed by a plurality of mutually independent first traces extending in the preset direction, the first traces are connected to the source/drain regions through the conductive plugs or the first traces are connected to the gate structures, each of the first traces connected to each of the source/drain regions comprises a first conductive portion and a second conductive portion that are isolated from each other, the first conductive portion is configured to extend in the preset direction and transmit an electrical signal, the second conductive portion is configured to serve as an intermediate transmission structure between a second conductive layer and the source/drain region, and the second conductive layer is located above the first conductive layer.

8. The memory layout according to claim 7, wherein in the preset direction, a length of the second conductive portion is less than a length of the source/drain region, and a length of the first conductive portion is greater than the length of the source/drain region.

9. The memory layout according to claim 7, wherein some of the first traces comprise the first conductive portion and two second conductive portions, and the two second conductive portions are located on two opposite sides of the first conductive portion.

10. The memory layout according to claim 1, further comprising a sense amplifier located between the adjacent memory arrays, wherein the sense amplifier is configured to sense and amplify data of a bit line;
the sense amplifier comprises an amplification transistor for performing sensing and amplification and a transmission transistor for transmitting a power signal, a direction of the transmission transistor toward the local amplifier is perpendicular to the preset direction, and a gate structure of the transmission transistor extends in the preset direction.

11. The memory layout according to claim 10, wherein the amplification transistor and the transmission transistor are arranged in the preset direction, and a gate structure of the amplification transistor extends in the preset direction.
